(19) United States
(12) Patent Application Publication
(10) Pub. No.: US 2010/0033075 A1
(43) Pub. Date: Feb. 11, 2010

(54) WHITE LGHT-EMITTING DIODE AND ITS FLUORINE-OXIDE PHOSPHOR POWDER

(76) Inventors: Soshchin NAUM, Changhua City (TW); Wei-Hung Lo, Taipei City (TW); Chi-Ruei Tsai, Taipei City (TW)

Correspondence Address: Guice Patents PLLC, 12647 Galveston Court #302, Manassas, VA, 20112, US

(21) Appl. No.: 12/481,681

(22) Filed: Jun. 10, 2009

(30) Foreign Application Priority Data
Jun. 20, 2008 (TW) 097123219

(51) Int. Cl. H01J 1/62; C09K 11/61; H01L 33/00; H01L 31/0304

(52) U.S. Cl. 313/486; 252/301.4 H; 257/86; 257/431; 257/E33.027; 257/E31.019

(57) ABSTRACT

The present invention discloses a fluorine-oxide phosphor powder, based on the cubic garnet fluorine oxide and yttrium aluminum oxide and using cerium as activator, is characterized in that the luminescent material is added with fluorine with a chemical equivalence formula as Y₃₋ₓCeₓAl₂(AlO_{4-γ}F_{O)γ}F_{i)γ})₃, wherein F_{O} is fluorine ion in the lattice point of oxygen crystal and Fᵢ is fluorine ion between the lattice points. The phosphor powder has cerium ions Ce⁺³ as activator and can be excited by quantum radiation or high-energy particles with energy between E≈2.8 eV and E→1 MeV to have a peak wavelength between λ=538˜548 nm and half bandwidth of Δλ_{0.5}=109-114 nm. Moreover, the present invention also discloses an In—Ga—N heterojunction used in spectrum converter, semiconductor light source, scintillating phosphor powder, scintillation sensor, and FED (Field Emission Display) monitor.

### FIELD OF THE INVENTION

The present invention relates to the field of electronics, in particular to a fluorine-oxide phosphor powder related to the modern technology field broadly called solid state lighting and a semiconductor light source employing the phosphor powder.

### BACKGROUND OF THE INVENTION

Rare-earth luminescent materials are the foundation of modern lighting technology with its main function as an energy saving lamps. Energy saving lamps still use the three primary color RGB phosphor powder, for example Y₂O₃:Eu, CeLaPO₄:Tb and BaMgAl₁₀O₁₇:Eu. The important constituent of PDP (Plasma Display Panel) phosphor screen is rare-earth RGB phosphor powder, in which BaMgAl₁₀O₁₇:Eu is for blue light, (Gd,Y,Tb)BO₃ for green light, and (Gd,Y,Eu)BO₃ for red light, and is excited to luminesce under YUV shortwave radiation. Current PDP mainly employs CRT (Cathode Ray Tube), which is based on Y₂O₂S:Eu, a rare earth material. Some rare-earth phosphor powder is applied in fluorescent lamps to ensure sharp images formed on LCD.

The rare-earth phosphor powder of Gd₂O₂S:Tb can also be used in X-ray imaging of human bodies. The phosphor powder of Y₂O₂S:Tb, on the other hand, is applied in special fields, x-y Ray Scanner for example.

The intersection of microelectronics and lighting technology leads to a new field, solid-state light sources. Rare-earth phosphor powder becomes indispensable when high-performance new light sources are created with this new technology. In semiconductor, the known yttrium-aluminum garnet phosphor powder with cerium as activator (YAG:Ce) can generate white light radiation with different color tones (please refer to Luminescence Material, by G Blasse, Springer, Amst, Berlig 1994).

The rare-earth phosphor powder is widely applied in nuclear physics and atoms dynamics. This luminescent material has been used in all radiation dosimeters found in all modern scientific and industrial fields. The above description has clearly explained that the rare-earth phosphor powder has a very variety of applications and it is indispensable.

The rare-earth phosphor powder has been used in many applications covering different fields of technologies. The present invention, however, would only focus on applying this material in the semiconductor light-emitting diodes (LEDs). In this particular field, the development has been based on |||AVB compounds, Ga(As,P) or (Al,Ga)P for example, and this technology has made a steady progress, creating unusual radiations of mainly red and green lights with a moderate luminescent brightness. This technology has been applied in small-size display to display images of different signals. This LED has a low performance with a brightness less than L=100 candela/m². A Japanese scholar S, Nakamura proposed a high-performance quantum framework of LEDs based on In—Ga—N (please refer to Blue laser, by S Nakamura, Berlig Springer, 1997) to resolve the technical problems of using white light-emitting diodes as a light source (please refer to U.S. Pat. No. 6,614,179S, S. Schimizu). Experts in Nichia Corporation have proposed to produce binary LEDs based on In—Ga—N semiconductor heterojunction, which generates white light comprising a small amount of primary blue light emission from heterojunction and a large amount of regenerated yellow light emission from phosphor powder. According to Newton's Law of Complementary Colors, the regenerated yellow light emission generated by YAG:Ce (Y,Gd,Ce)₃(Al,Ga)₅O₁₂ phosphor powder combined with blue light emission of the heterojunction can lead to white light emission.

YAG:Ce phosphor powder is one of a series of rare-earth oxides phosphor powder; its characteristics (parameters) are generally determined by one of the bi-component activators. The radiation performance of the semiconductor luminescent materials is determined by the main composition of the trace amount of activator added into the phosphor powder. According to this criterion, the luminescent materials based on ||AV|B compounds (e.g. the mixture consisting of oxides, sulfides, telluride, and the trace activation ions Ag⁺¹ or Cu⁺² or oxygen ions) are considered semiconductor phosphor powder. When the concentration of the trace amount of activator Ag+1 remains unchanged, the ||AV|B semiconductor phosphor powder can generate blue, green, yellow, and red radiations with the changing concentration ratio of ZnS and CdS. On the other hand, the phosphor powder using Eu⁺ ions as activator can only generate red-orange or red radiation even if the composition and chemical framework are changed.

It has to point out that a large amount of researches have produced many “medium level” phosphor powder, for example, broad band S₂Al₂O₄ phosphor powder and narrow band Lu₂O₂S (rare-earth sulphur oxide) phosphor powder or LuOBr (rare-earth bromine oxide) phosphor powder. The sulphur or bromine ions of the phosphor powder produce an additional “charge-transfer band” between the main ions and activator ions.

However, it is beyond doubt that there exist two large categories of phosphor powder. In general, these phosphor powders have (1) broad band gap Eg≧4.8 eV, (2) single phase crystal, and (3) single-charge cathodic or anodic ions sub-crystal.

These phosphor powders usually consist some stable constituents; for example, (PO₄)⁻³, (SO₄)⁻², (Si₂O₄)⁻², (Si₂O₇)⁻², and so on. Also, it can be seen from the above constituents that the function of each O⁻² cannot be overlooked. According to the principle, the phosphor powder with the composition of Y₃Al₅O₁₂ is taken as an analogue. The framework of this phosphor powder is YO₈ and AlO₄. It is worth pointing that the structure of this phosphor powder contains ligand, i.e. oxygen ions, O⁻².

The known phosphor powder has a series of characteristics. First, for the phosphor powder with such a composition, its spectral composition tends to shift to long wavelength side of the visible spectrum. So far, there are four known ways to shift the spectrum to long wavelength. Adding cerium ions and activor ions (Pr⁺³, Sm⁺³ or Eu⁺³ or Dy⁺³) can generate additional radiation band, which can shift the dominant wavelength by 5˜10 nm. Alternatively, the aliovalent ionic substitution in anion sub-crystals, Al⁺³ substituted with Si⁺⁴ and Mg⁺², can shift the dominant wavelength by 6˜12 nm.

It is much more convenient to substitute Y⁺³ ions with rare earth ions Gd⁺³ in an isovalent manner. In practical, the latter method has been applied more widely and can change the radiation spectrum of the phosphor powder by 25˜35 nm. In addition, the isovalent ionic substitution of Al⁺³ ions with Ga⁺³ ions in the anion sub-crystal of the phosphor powder can even shift the radiation spectrum into short wavelength. This method has been successful in shifting the radiation spectrum of the phosphor powder into short wavelength by 6˜8 nm.

The phosphor powder with the composition of Y₃Al₅O₁₂:Ce has another important characteristic; i.e. the excitation spectrum is stable in the region λ=450˜470 nm. This band is closely related to ⁵D₂ transition in Ce⁺³ ions. Also, in practical, regardless of the addition of activators into or isovalent substitution for the composition of the phosphor powder, the excitation spectrum remains unchanged.

The phosphor powder with the composition of Y₃Al₅O₁₂:Ce has one further characteristic: a very high quantum output of radiation. The high quantum output can be seen from the ratio of the quantum number of the phosphor powder and the quantum number absorbed by excited light. Moreover, it is necessary to point out once again that the quantum output of the phosphor powder can be obtained from accurate calculation of the quantum number of excited light. Undoubtedly, the raw materials and heat treatment process of the phosphor powder will affect the output of quantum number. However, the phosphor powder with the composition of Y₃Al₅O₁₂:Ce generally has a standard quantum output of η=0.75˜0.90, which is the very important advantage of yttrium-aluminum phosphor powder. Under a certain synthesis process for the phosphor powder, a very high lighting parameter can certainly be obtained and this is the main reason why the phosphor powder with a garnet structure can be widely used in white LEDs.

However, the known phosphor powder has certain substantive drawbacks. First, the particles size is too large. In general, the mean particles size of the synthesized yttrium-aluminum garnet phosphor powder is d_{cp}=6˜8 μm, and its median particles size is d₅₀=4˜6 μm. In the packaging process of LEDs, the particles size does not pose a difficulty for manual process since a multi-layer structure will be formed during packaging and larger particles of phosphor powder will form the first layer and smaller particles form the second layer on the surface of the first layer, and so on. In an automatic packaging process, however, large particles of phosphor powder will form suspensions on the surface of heterojunction, cover the hole of wire drawing die, and damage the light radiation of LEDs, rendering the radiated light uneven.

In general, when original particles of phosphor powder are mechanically crushed, not only the luminescent brightness of the phosphor powder will be reduced substantially (15˜25%), but also its calorimetric characteristics (chromaticity coordinates, color temperature, peak wavelength) will be radically changed.

All known low-temperature synthesis processes for the garnet phosphor powder, for example sol-gel process (please refer to the U.S. patent publication No. 200727851 anticipated by N. Soschin et al.) or co-precipitation process, do not produce phosphor powder with a high lighting quality. Consequently, the particles size has been the most important issue for the synthesis process. To solve the problem is also beneficial to the enhancement of the lighting parameters for the yttrium-aluminum garnet phosphor powder.

Another important disadvantage of the yttrium-aluminum garnet phosphor powder is that the radiation spectrum curve cannot be controlled. As we have pointed out, different choices of phosphor powder ingredients and improving the synthesis technology cannot change the curve (which can be described by Gauss function). The un-changeability of the radiation spectrum curve for phosphor powder has complicated the choice of the main radiation color for white LEDs.

One further important disadvantage of the yttrium-aluminum garnet phosphor powder is that since a substantial amount of gadolinium (Gd) is added (75% or more), the light generated by the phosphor powder under the excitation of high power is unstable in term of temperature. It is necessary to point that for all the phosphor powder with the composition of (Y_{3-x-y}GdₓCe_{y})Al₅O₂, the aforementioned drawback will be revealed under the shortwave excitation of heterojunction, under the excitation of electron radiation (CRT, for example), or even under the excitation of the large amount of radiation in scintillation sensor.

Many approaches have been developed to eliminate the drawbacks of the known phosphor powder. One of the approaches undertaken in a patent by one of the present inventors (please refer to the patent application WO 02099902 by A Srivastava and the patent application White Light Source, WO 015050, by N Soschin) proposed that the ingredient of the phosphor powder is based on the solid solution of two inter-soluble aluminum oxides—spinel with the composition of Me⁺²Al₂O₄:Ce⁺³ and garnet, (Y,Gd,Ce)₃Al₅O₁₂.

Unlike the known phosphor powder, the crystal structure of the phosphor powder according to the present invention is not only cubic but also changeable. The present invention proposes the process for inter-soluble hexagonal and rhombohedral solids. The existence of multiple phases enables the control of the particle size during the synthesis of phosphor powder.

Secondly, by selecting the ingredient of the new phosphor powder made of inter-soluble solids, the half bandwidth of the radiation spectrum of the phosphor powder can be specifically controlled.

Thirdly, there is no need to add a large amount of Gd⁺³ ions to create a phosphor powder with saturated yellow or orange-yellow light. The direct consequence of a phosphor powder without a large amount of gadolinium is that the radiation being dependent on the temperature of LEDs heterojunction and the non-linear characteristics of excitation powder are no longer valid.

Nowadays, many companies in Russia, China, and Taiwan have employed this synthesized phosphor powder to produce white LEDs. Although this kind of phosphor powder has many substantive advantages, it has many drawbacks; its calorimetric performance is difficult to reproduce because the particles size of the ingredient of the phosphor powder is not uniform during synthesis. Therefore, several detailed examinations have to be conducted during the synthesis process, especially for the ingredient of carbonate or hydroxide. Moreover, the performance achieved by the synthesized phosphor powder is limited, typically 101˜102% of the performance of the standard sample.

In summary, there are two major ingredients of phosphor powder for white LEDs—garnet YAG:Ce and spinel-garnet. If YAG:Ce garnet phosphor powder is based on partial cerium and the complete inter-soluble solids of yttrium-gadolinium-aluminum garnet, the spinel-garnet phosphor powder can be based on aluminum oxide spinel and aluminum garnet, which are partially soluble synthetics, during the synthesis process. The valence cluster of the composition of the YAG:Ce garnet phosphor powder is based on yttrium ions Y⁺³ (or gadolinium ions, Gd⁺³) which has a coordination number of eight, and aluminum ions Al⁺³ which has a coordination number of six and four. On the other hand, the spinel-garnet phosphor powder with garnet structure has its valency cluster with coordination number of ten and twelve. These two ingredients differ in one important aspect; the former has a single phase and the latter has multiple phases.

TABLE 1 clearly describes the difference between these two phosphor powders.

TABLE 1

| | | Spinel-garnet synthesized |
|---|---|---|
| Characteristics | YAG:Ce garnet ingredient | ingredient |
| Oxides ratio | Y₂O₃:Al₂O₃ = 3:5 | Y₂O₃:Al₂O₃ ≧ 3:5 |
| Different solid | Completely mutual solubility: | MeAl₂O₄ is partially |
| solution | Y₃Al₅O₁₂—Gd₃Al₅O₁₂ | soluble in Y₃Al₅O₁₂ |
| | Partial mutual solubility: | |
| | Y₃Al₅O₁₂:Ce₃Al₅O₁₂ | |
| Structure | Cubic | Multiple phase, a mixture |
| Space lattice | O¹⁰ₙ-1a3d | of cubic and hexagonal |
| | | Unknown |
| Coordination | 4, 6, 8 | 4, 6, 8, 10, 12 |
| number | | |
| Ligand | O⁻² ions only | O⁻² ions only |

From TABLE 1, it can be seen that these two phosphor powders are different in both the constitution of phases as well as the solid solutions obtained.

### SUMMARY OF THE INVENTION

To overcome the prior drawbacks described above, the main objective of the present invention is to provide a fluorine-oxide phosphor powder, which is a compound with different ligands and is a solid solution with completely mutual solubility in terms of concentration.

To overcome the prior drawbacks described above, another objective of the present invention is to provide a fluorine-oxide phosphor powder, whose spectrum parameters and calorimetric parameters are not determined by the isovalence or aliovalence of the formed solid solution, but by the different ligands found around the main polyhedron (atom cluster) of the compound.

To overcome the prior drawbacks described above, a further objective of the present invention is to provide a fluorine-oxide phosphor powder, which fundamentally changes the spectral peak wavelength of the phosphor powder and shifts the peak wavelength to the short wavelength of radiation.

To overcome the prior drawbacks described above, another further objective of the present invention is to provide a fluorine-oxide phosphor powder, which may be applied in narrow-band emitters to accurately detect all color tones of radiation and which is an extremely important phosphor powder because a phosphor powder with such a composition can achieve a very high luminescence performance under the excitation of LEDs with any current and power.

To overcome the prior drawbacks described above, a further objective of the present invention is to provide a synthesis process for the fluorine-oxide phosphor powder to reduce the production cost.

To achieve the aforementioned objectives, a fluorine-oxide phosphor powder according to the present invention, based on the cubic garnet fluorine oxide and yttrium aluminum oxide and using cerium as activator, is characterized in that the luminescent material is added with fluorine with a chemical equivalence formula as Y₃₋ₓCeₓAl₂(AlO_{4-γ}F_{O)γ}F_{i)γ)}₃, wherein F_{O} is fluorine ion in the lattice point of oxygen crystal and Fᵢ is fluorine ion between the lattice points.

To achieve the aforementioned objectives, a spectrum converter according to the present invention used in In—Ga—N heterojunction and based on the aforementioned phosphor powder, is filled with the phosphor powder in its transparent polymer layer and is characterized in that the spectrum converter is formed as a geometrical shape with a uniform thickness and becomes a light source by optically contacting with the planes and side planes of the heterojunction, its radiation spectrum consists of the primary radiation of λ=450˜470 nm short-wavelength heterojunction and the regenerated radiation of the aforementioned phosphor powder, and the filled phosphor powder has an appropriate concentration to produce white light with a color temperature of T=4100˜6500K.

To achieve the aforementioned objectives, a semiconductor light source according to the present invention based on spectrum converters and having the aforementioned spectrum converters on the planes and facets of the In—Ga—N heterojunction, is characterized in that the overall radiation comprises two spectrum curves, of which the first spectrum curve has the peak wavelength at λₘₐₓ=460±10 nm and the second spectrum curve has the peak wavelength at λₘₐₓ=546±8 nm, with the chromaticity coordinate being x=0.30˜0.36 and y=0.31˜0.34.

To achieve the aforementioned objectives, a scintillating phosphor powder according to the present invention having the aforementioned composition is characterized in that the mean diameter of the particles is d≧=10 μm, the median diameter is d≧5±0.5 μm, the specific area is S≦18×10³ cm²/cm³, and the phosphor particles excited by γ ray with energy E=1.6 MeV or high-energy particles can scintillate.

To achieve the aforementioned objectives, a scintillation sensor according to the present invention based on the aforementioned phosphor powder, which is distributed in transparent polymer, polycarbonate, with an average molecular weight M=18˜20×10³ carbon unit and which accounts for 40% of mass in the scintillation sensor, is characterized in that the scintillation sensor scintillates 38˜52×10³ time/second under the excitation of 1 MeV particles or γ radiation quanta.

To achieve the aforementioned objectives, a glass tube according to the present invention on its inner surface having a light radiation layer, which has the aforementioned fluorine-oxide phosphor powder, is characterized in that the air of the light radiation layer contains the tritium isotope, ₁T³, emitting Fray with energy E=17.9 keV, which excites the phosphor powder particles to luminesce with an initial luminescent brightness L=2˜4 candela/m² and decay 25% of the luminescent brightness in 3.5˜4 years.

To achieve the aforementioned objectives, a FED (Field Emission Display) monitor according to the present invention, in which the radiation emitted from its anodic phosphor powder layer is related to the impingement of electron beams, is characterized in that the composition of the phosphor powder particles of the phosphor powder layer is consistent with that of the aforementioned fluorine-oxide phosphor powder which emits yellow-green light under the excitation of electron with energy E=250˜1000 eV.

To achieve the aforementioned objectives, a display containing phosphor powder layer according to the present invention is characterized in that the mean diameter of the particles of the phosphor powder layer is d_{cp}≦1 μm and the median diameter is d₅₀≦0.6 μm.

### BRIEF DESCRIPTION OF THE DRAWINGS

The present invention can be more fully understood by reference to the following description and accompanying drawings, in which:

FIG. 1 illustrates the spectrum analysis of the phosphor powder, in which the ratio of O⁻² to F⁻¹ is 3.5:1;

FIG. 2 illustrates the spectrum analysis of the phosphor powder, in which the ratio of O⁻² to F⁻¹ is 4.5:1;

FIG. 3 illustrates the spectrum analysis of the phosphor powder, in which the ratio of O⁻² to F⁻¹ is 7.5:1;

FIG. 4 illustrates the spectrum analysis of the phosphor powder, in which the ratio of O⁻² to F⁻¹ is 15.5:1;

FIG. 5 illustrates the spectrum analysis of the phosphor powder, in which the ratio of O⁻² to F⁻¹ is 31.5:1;

FIG. 6 illustrates the spectrum analysis of the phosphor powder, in which the ratio of O⁻² to F⁻¹ is 49.5:1; and

FIG. 7 illustrates the morphology of the phosphor powder particles, in which the ratio of O⁻² to F⁻¹ is 15:1.

### DETAILED DESCRIPTION OF THE INVENTION

First, the objective of the present invention is to overcome the drawbacks of the aforementioned phosphor powder and the semiconductor light source using the phosphor powder. To achieve the aforementioned objectives, a fluorine-oxide phosphor powder according to the present invention based on the cubic garnet fluorine-oxide and yttrium aluminum oxide and using cerium as activator, is characterized in that the luminescent material is added with fluorine with a chemical equivalence formula as Y₃₋ₓCeₓAl₂(AlO_{4-γ}F_{O)γ}F_{i)γ})₃, wherein F_{O} is fluorine ions in the lattice points of oxygen crystal and Fᵢ is fluorine ion between the lattice points;

wherein the stoichiometric indexes of the stoichiometric equivalence formula are 0.001≦γ≦1.5 and 0.001≦x≦0.3, and the lattice parameter of the luminescent material is a≦1.2 nm.

The fluorine-oxide phosphor powder has a broad-band excitation spectrum of wavelength λₑₓₜ=380˜470 nm, the peak wavelength of λ=420˜750 nm, the peak wavelength of λₘₐₓ=538˜555 nm, and the maximum half bandwidth of λ_{0.5}=109˜114 nm.

When the excitation wavelength of the phosphor powder is λ=458 nm, the lumen equivalence of the radiation spectrum fluctuates in the range of QL=360-460 lumen/watt.

The phosphor powder excited by near violet-visible light emits yellow-green light with the peak wavelength of λ=538-555 nm.

The afterglow period of the phosphor powder is τₑ=60-88 nanoseconds when excited by the light of λ=450-470 nm.

The reflection index R of the phosphor powder is less than 20%, R≦20%, in the short-wavelength sub-energy band of λ=400˜500, and the reflection index in the yellow-green zone of the spectrum is R=30-35%.

The luminous intensity of the phosphor powder decreases by 12˜25% when T=100˜175° C.

Under the excitation band of λ=460±10 nm, the radiation quantum output of the fluorine-oxide phosphor powder is η≧0.96 and the quantum output increases with increasing concentration of fluorine ions from [F]=0.01 to [F]=0.25.

The radiation spectrum of the phosphor powder can be represented by Gauss curve and the dominant wavelength increases from λ=564 nm to λ=568 nm.

The particles of the phosphor powder are roughly spherical with 12 and/or 20 facets and have a mean diameter d_{cp}=2.2˜4.0 μm, a median diameter is d₅₀=1.60˜2.50 μm, and also a specific area reaches 42×10³ cm²/cm³.

The physical chemistry principle of the fluorescent powder according to the present invention is outlined hereinafter. First, the phosphor powder with garnet structure is characterized by the coordination polyhedron of its anion sub-crystal. The coordination number of the Al⁺³ in the coordination polyhedron is 6. When Al⁺³ ions are situated in the tetrahedron AlO_{4-γ}F_{O)γ}, its coordination number is 4. The second characteristic of the phosphor powder is the different ligands around the main ions in its anion and cation crystals. These different ligands in the anion sub-crystal are located around the tetrahedron of Al⁺³ ions. Also, the ratio of ligand ions O⁻² and F⁻¹ is changeable and affect the radiation parameters of the phosphor powder.

There is another important characteristic of the phosphor powder according to the present invention: the amount of yttrium, cerium, aluminum, oxygen, and fluorine in the chemical equivalence formula is limited. To perfect the composition of the phosphor powder, the addition of certain new elements is necessary. The methods adopted so far are limited to atoms addition.

Another further characteristic of the phosphor powder according to the present invention is that the lattice parameter of the tetragonal crystal is reduced to a 1.2 nm, which is a critical value for yttrium-aluminum garnet phosphor powder.

The crystal chemistry of the new phosphor powder according to the present invention is characterized by (1) single phase; (2) different ligands found around the main ions in the cation and anion sub-crystals; (3) the sizes of ligands being different.

In addition, some other less obvious characteristics are needed. It is possible that when fluorine ions substitute oxygen ions, the aliovalency mechanism is always followed, but the locations of fluorine ions are different. One possible approach is to create effective positive charge lattice point Fₒ, However, the lattice point can undergo the reaction, Oₒ=(Fₒ)°+(Fᵢ)′, between the lattice points in the crystal.

From the compounds according to the present invention, some processing methods can be found to produce phosphor powder with high-performance parameters, including brightness, color, narrow band, speed or afterglow of excitation decay, spectrum radiation intensity, and color restitution coefficient. When Gd and/or Lu is added into the phosphor powder, or Ga ions are added into anion sub-crystal, the ratio of activator cerium ion and main ion yttrium, Ceₓ/Y₃₋ₓ, has a significant influence on the spectrum characteristics of the phosphor powder. If the concentration of cerium is increased by ten times, from [Ce⁺³]=0.005 to [Ce⁺³]=0.05 atomic fraction, the change of the chromaticity coordinate x will be Δx=+0.025 and that of y will be Δy=+0.02, and the total change of the chromaticity coordinates will be Σ(Δx+Δy)=0.045, which is 6% of the total value of the radiation chromaticity coordinates; the change is not significant. Alternatively, the concentration of activator ion cerium can be reduced, but it will substantially reduce the brightness of the phosphor powder, and thus it is not a viable option. On the other hand, the concentration of the activator ion cerium can be increased substantially to enhance the change of the chromaticity coordinates; however, the phenomenon of brightness quenching has to avoid. Therefore, the approach should be based on the proposed Σ(Δx+Δy)=0.045.

The second approach concerns the ratio of the main oxide compounds of the phosphor powder, i.e. changing the ratio between Y₂O₃ and Al₂O₃ to be different from the chemical equivalence ratio 3:5=0.6 proposed in the Taiwan Patent No. 249567B authored by the inventors of the present invention. From the data obtained earlier, the present inventors propose to increase the chemical equivalence ratio of Y₂O₃/Al₂O₃ by 0.01, i.e. to 0.61, and the change of the chromaticity coordinates will be Δx=0.005. If increasing the change by five times, i.e. Y₂O₃/Al₂O₃=0.65, the change of the chromaticity coordinates is Δx=0.03. It is unfortunate that increasing the ratio of aluminum oxide to yttrium oxide will reduce the chromaticity coordinate y by Δy=−0.025. Therefore, in the context of the spectrum constitution and radiation color of the phosphor powder brought up by the change, the first approach (changing the concentration of activator ion cerium) is more suitable than the second one.

However, the phosphor powder according to the present invention is found to have an unusual characteristic: the concentration ratio of ligands in the composition of the phosphor powder greatly affecting the parameters of calorimetric, spectrum, and brightness. It is found that when the oxygen concentration is [O]=11.9, the concentration of fluorine ion is [F]=0.2 atom fraction; when the oxygen concentration is [O]=8, the concentration of fluorine ion is [F]=8. When the ratio of two different ligands (fluorine and oxygen), fluctuates in a given range, the peak wavelength changes from λ=550 nm to λ=532 nm correspondingly. The chromaticity coordinate “x” changes from x=0.3492 to x=0.4049, i.e. Δx=0.07; the chromaticity coordinate “y” from y=0.4369 to y=0.5062, i.e. Δy=0.07. With x and y combined together, the total chromaticity coordinates increases by Σ(Δx+Δy)=0.14.

Compared with the previous approaches of changing the concentration of activator ion cerium or the chemical equivalence coefficient “γ,” changing different concentration of different ligands has a larger effect on the optical properties of the phosphor powder. It is clearly revealed that the change of the ratio of ligands O and F has a much larger effect.

The effects of different ratios of ligands on the phosphor powder according to the present invention manifest not only on the change of chromaticity coordinates of the phosphor powder, but also on the change of the peak wavelength from λ=550 nm to λ=532 nm (Δλ=18 nm).

The change of half-band width of the radiation spectrum is also significant, reaching Δλ_{0.5}=15 nm. With the average parameter λ_{0.5}=112 nm, the change is 13.4%, exceeding the possible error of the radiation curve of phosphor powder.

The luminescent brightness of the phosphor powder with different ligands according to the present invention has changed significantly. When the brightness of the standard sample is LN≈30000 units, the brightness of the phosphor powder according to the present invention has changed from L=27740 to L=36111 units, a change of 28%, which is substantial.

When the change of the peak wavelength is Δλ=18 nm, the change of the dominant wavelength is not substantial, Δλ=7 nm. The radiation dynamics parameter of the phosphor powder proposed in certain individual experiments has changed. When the average afterglow duration is τₑ=92 nano-seconds, the parameters are τₑ=76 and τₑ=106 nano-seconds.

The experimental data (which will be shown in TABLE 2) obtained can be summarized as follows: with the change of the amount of ligands, i.e. the change of concentration of O⁻² and F⁻¹ ions, the calorimetric and spectral characteristics have also experienced substantive changes.

There is an important experimental finding to report; the concentration ratio of ligands O⁻² and F⁻¹ is determined by the raw materials used in the experiment conducted by the present inventors. Yttrium oxide (Y₂O₃) and aluminum oxide (Al₂O₃) and/or yttrium fluoride (YF₃) and/or yttrium oxyfluoride (YOF) are taken as the raw materials for the phosphor powder according to the present invention. The chemical equivalence formula obtained is YF₃+Y₂O₃+2.5 Al₂O₃═Y₃Al₂(AlO_{3.5}F)₃, (stoichiometry equation 1). In fluorine-oxide garnet, the ratio of O⁻²/F⁻¹ is O⁻²/F⁻¹=10.5:3.0=7:2 unit. This explains that the final synthesized phosphor powder according to the present invention is seven oxygen ions to two fluorine ions. For stoichiometry equation 1, it is necessary to follow the chemical stoichiometry of reagents and the final product. However, for three fluorine ions, they do not contribute to the chemical formula according to mass balance, but one and half oxygen ions are excessive. It is pointed out that the excessive ions will be changed between the lattice points in the garnet crystal according the number of lattice point. Under this condition, stoichiometry equation (1) should be rewritten as: YF₃+Y₂O₃+2.5Al₂O₃→Y₃Al₂(AlO_{3.5}F_{O)0.5}F_{i)0.5})₃ (stoichiometry equation 2). Stoichiometry equation (2) clearly indicates that the relationship between the fluorine ions and oxygen ions added as well as the specific sites for fluorine ions between lattice points in the oxygen lattices points.

The stoichiometry equation (1) is assessed by weighting method; the mass of the product is similar to that of the original reagents; the former is only 0.5˜1% higher. This consistency confirms the high validity of the stoichiometry equation 1 and it is possible that the Stoichiometry equation (2) will be followed with the change of excessive fluorine ions between lattice points.

The ingredients for the phosphor powder according to the present invention are obtained, in which the atomic ratio of O⁻² and F⁻¹ ions is as follows:

| | |
|---|---|
| Y₃Al₂{AlO_{3.5}F₁}₃ | 3.5:1 |
| Y₃Al₂{AlO_{3.6}F_{0.8}}₃ | 4.5:1 |
| Y₃Al₂{AlO_{3.75}F_{0.5}}₃ | 7.5:1 |
| Y₃Al₂{AlO_{3.875}F_{0.25}}₃ | 15.5:1 |
| Y₃Al₂{AlO_{3.9375}F_{0.125}}₃ | 31.5:1 |
| Y₃Al₂{AlO_{3.96}F_{0.08}}₃ | 49.5:1 |

Table 2 lists the parameters obtained experimentally for the phosphor powder according to the present invention.

TABLE 2

| Sample | | Peak wavelength, | Chromaticity | Luminescent | Half bandwidth, |
|---|---|---|---|---|---|
| No. | O:F ratio | nm | coordinates x, y | brightness | nm |
| 1 | 3.5:1 | 532 | 0.3492, 0.4431 | 27740 | 124.8 |
| 2 | 4.5:1 | 538.9 | 0.3421, 0.4369 | 29369 | 119.3 |
| 3 | 7.5:1 | 542.4 | 0.3804, 0.4818 | 32665 | 111.9 |
| 4 | 15.5:1 | 544.0 | 0.3872, 0.4906 | 32642 | 110.8 |
| 5 | 31.5:1 | 546 | 0.3878, 0.4860 | 36229 | 110.9 |
| 6 | 49.5:1 | 547.6 | 0.4049, 0.5062 | 33165 | 109.9 |
| 7 | Standard | 550 | 0.3650, 0.4150 | 30000 | 124.0 |
| | 12:0 | | | | |

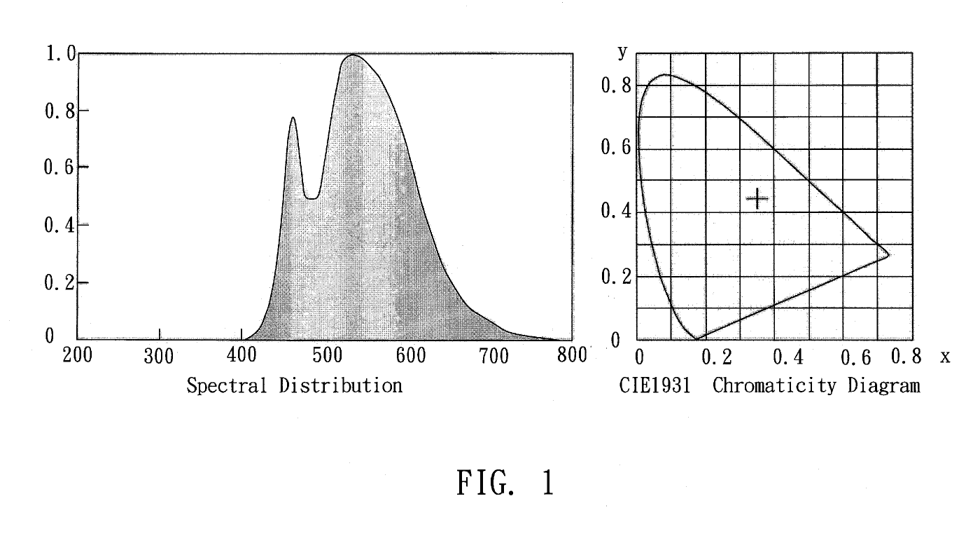

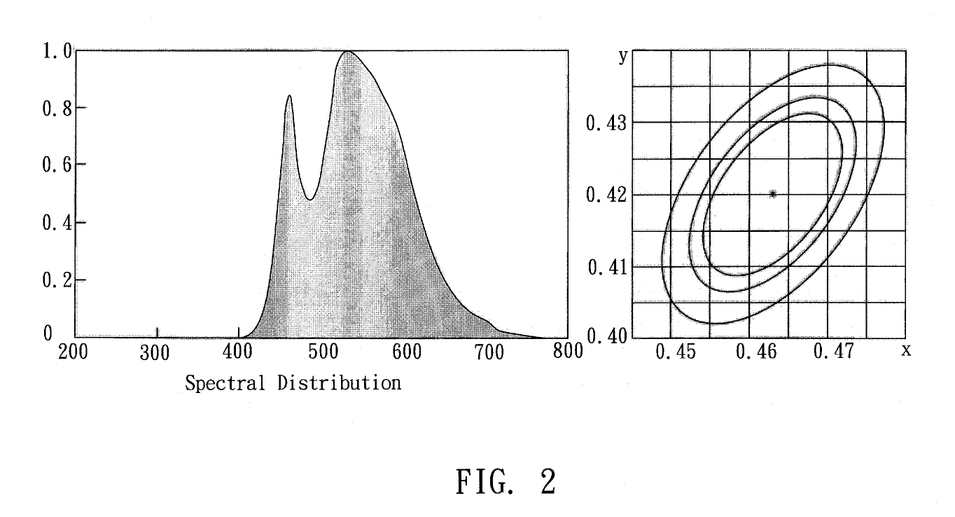

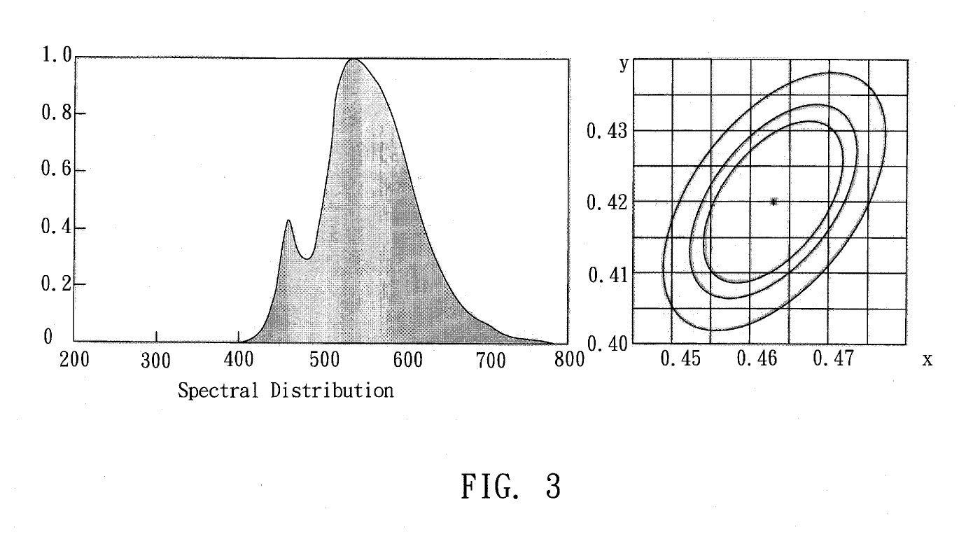

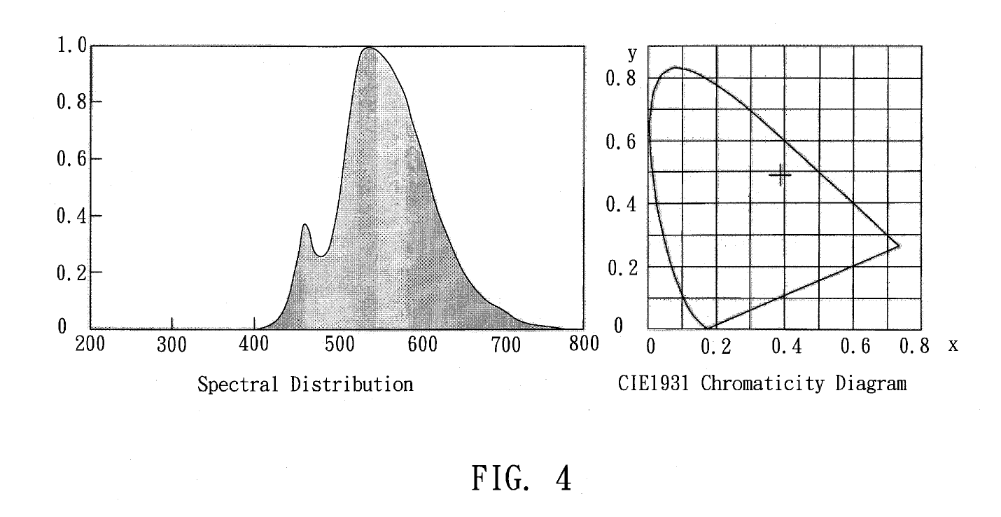

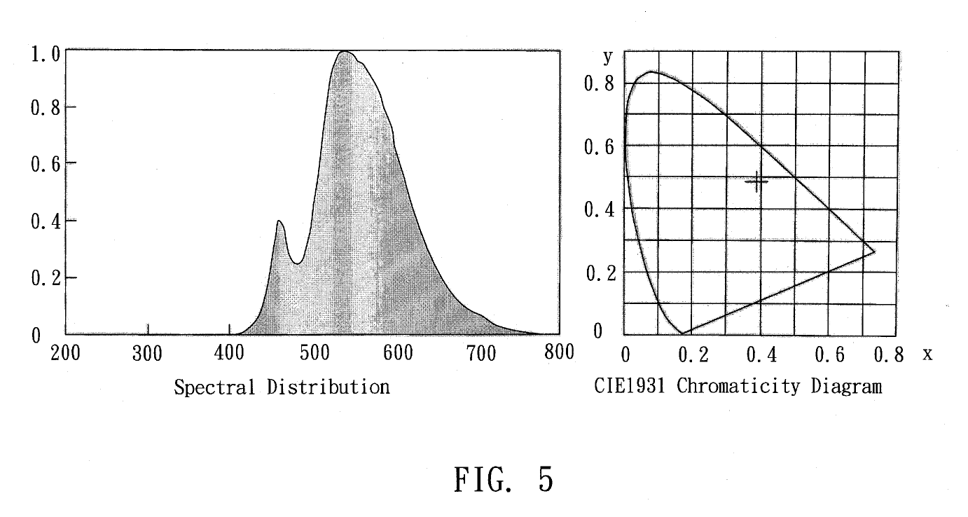

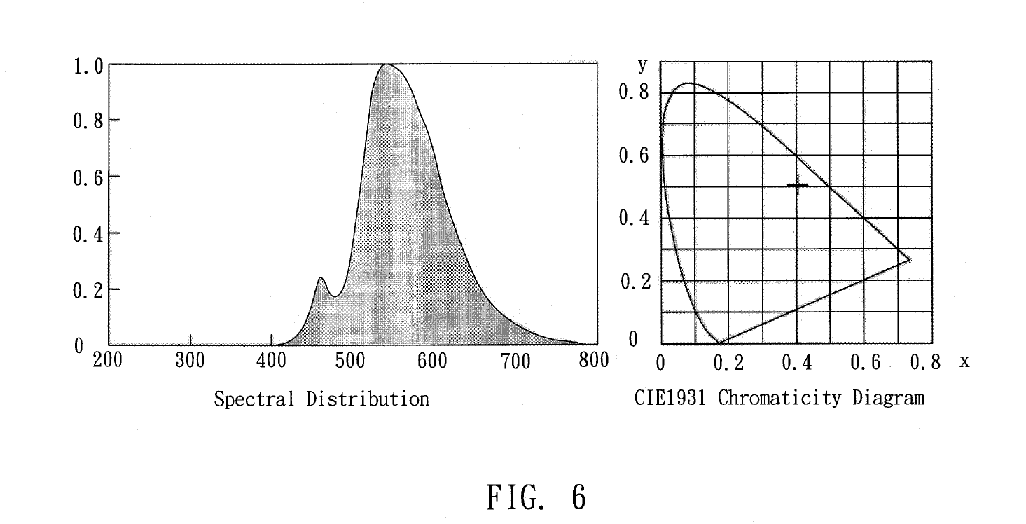

FIGS. 1 to 6 are the corresponding radiation spectrums of the synthesized phosphor powders. The radiation spectrums are obtained under standard conditions (the phosphor powder is excited by the radiation of In—Ga—N LED with excitation voltage U=3.5V and current 1=20 mA) using spectroradiometer. For the phosphor powder in FIG. 1, the ratio of O⁻² and F⁻¹ is 3.5:1. For the phosphor powder in FIG. 2, the ratio of O⁻² and F⁻¹ is 4.5:1. For the phosphor powder in FIG. 3, the ratio of O⁻² and F⁻¹ is 7.5:1. For the phosphor powder in FIG. 4, the ratio of O⁻² and F⁻¹ is 15.5:1. For the phosphor powder in FIG. 5, the ratio of O⁻² and F⁻¹ is 31.5:1. For the phosphor powder in FIG. 6, the ratio of O⁻² and F⁻¹ is 49.5:1.

Moreover, the standard sample in TABLE 2 does not contain fluorine ions (F⁻¹). TABLE 2 indicates that the parameters of all the phosphor powders with two ligands are substantially different from those of the standard sample, including total sum of chromaticity coordinates (ΣΔx+Δy), luminescent brightness, the peak wavelength and half bandwidth. The analysis of how these parameters are changed with the ratio O⁻²:F⁻¹ will described as follows: (1) The peak wavelength increases with increasing O⁻²:F⁻¹ ratio from 3 to 50; (2) the total sum of chromaticity coordinates experiences a similar increase; (3) the luminescent brightness of the phosphor powder reaches the maximum when O⁻²:F⁻¹=31.5:1; (4) the minimum half bandwidth can reach Δλ_{0.5}=109.9 nm.

The changes of the data cited above are not consistent, indicating that there is no single physical reason behind the change. It is difficult to understand the ratio concerned simply from the quantitative perspective; in a unit cell of a garnet cubic crystal structure, there exists a space group of Z=8 unit. There are 160 atoms entering a unit cell: 24 Y atoms of coordination number K=8, 16 Al atoms of coordination number K=6, 24 O atoms of coordination number K=4, and 96 O atoms.

The ratios of the main atoms of the phosphor powder according to the present invention are kept the same as the previous values, but the atomic ratio of ligands is changed. When O⁻²:F⁻¹=3:1, there are 72 oxygen atoms and 24 fluorine atoms in a unit cell. When the ratio increased to 15:1, there will be 90 oxygen atoms and 6 fluorine atoms. When the ratio is increased to 23:1, there will be 92 oxygen atoms and 4 fluorine atoms in a unit cell. When the ratio is further increased to 47:1, there will be 94 oxygen atoms and 2 fluorine atoms correspondingly.

These data indicate that when the ratio of oxygen and fluorine is minimum, O:F=3:1, eight atoms form six lattice points on oxygen ions and two lattice points on fluorine ions within the coordination range of Y ions (or isovalent activator ion Ce⁺³. First, the above result explains that there lacks of atoms filling with equal mass and equal charge within the coordination range. Second, the different substitution of fluorine ions is possible; for example, two ions are placed side by side or through two oxygen ions. Consequently, the symmetric coordination polyhedron of Y atoms (or isovalent activator cerium ion, Ce⁺³) becomes an asymmetric coordination. This coordination style is formed by different masses of O⁻² and F⁻¹, but it is important that these ions have different charges: −2 for O⁻² and −1 for F⁻¹. The inventors found experimentally that when the ratio of ligands of the phosphor powder are changed to different charges within the coordination range of the main elements, the following results will be obtained: (1) the lattice parameters of the phosphor powder will be changed; (2) the radiation curve of the activator ion Ce⁺³ will not be symmetrical; (3) the half bandwidth of the spectrum will be changed.

It is found that the crystal structure of the phosphor powder is indeed symmetrical cubic, but its lattice is dependent on the amount of fluorine ions added into the crystal. When the ratio is O⁻²:F⁻¹=3:1 in the phosphor powder, the lattice parameter is a=1.190 nm.

The reason for the decrease of the lattice parameter is first because the ionic radii of fluorine and oxygen ions are different; the radius of fluorine ion is τ_{F}=1.33 A and that of oxygen ion is τ_{O}=1.36A. A large amount of fluorine ions in the phosphor powder will make the crystal structure denser, and thus reduce the lattice parameter. It has to point out that the garnet phosphor powder synthesized in the present invention has a lattice parameter of a=1.192 nm, which is a minimum value and close a=1.91 A of yttrium-aluminum garnet and a=1.909 A of lutetium-aluminum garnet.

This kind of reduced lattice parameter will likely to enhance the electrostatic field inside the crystal because the activator ions Ce⁺³ found inside the electrostatic field will enhance the re-combination probability of the radiation for the excitation transition points ⁵D₂ inside and upon of the ions.

However, the expansion of crystal field demands further explanation. For the constituent {AlO₃,F_{O)1}Fᵢ₎₁} in the phosphor powder, there is one fluorine ligand on three polydentate ligands O⁻². Therefore, the effective negative charge will be weakened by ⅛. In the new phosphor powder, there are 7=3×2(O⁻²)+1×1(F_{O)1}⁻¹). The crystal field weakened first will be strengthened after the addition of fluorineions, F⁻¹. Consequently, the large amount of charges will not be reduced and the charge will be near the central position. Since the decrease of lattice parameter is related to the addition of fluorine ions and the fluorine ions, Fᵢ₎⁻¹, between lattice points are located close to the geometric center of the constituent. It is difficult to quantitatively assess the effectiveness of the charge expansion according merely to the data of crystal chemistry.

For the composition of the phosphor powder, there is one lattice point ion F⁻¹ for three oxygen ions, with a reduction of effectiveness by 3˜5%. It is possible that the value is consistent with the enhancement of the internal crystal field. When the composition of the phosphor powder is added with a large amount of fluorine ions, F⁻¹, the crystal will be compressed and, in the mean time, the lattice parameter of the garnet crystal will be decreased. The internal force field becomes asymmetrical because part of the two-charge oxygen ions, O⁻², is substituted with one-charge fluorine ions, F⁻¹. The asymmetrical distortion of the internal electrical field will first broaden the radiation spectrum of activator ions Ce⁺³. This broadened spectrum will not affect the brightness. Since most of the broadened part of the spectrum is long wavelength, whose luminous efficacy is low, the brightness will be reduced intrinsically.

When the contraction fraction of the substituted oxygen atoms is low, the internal force field of the phosphor powder will be distorted. Distortion only occurs when the long wavelength of the spectrum is shifted 1˜3 nm and the change of the half bandwidth is Δλ_{0.5}=±1 nm.

If the concentration of fluorine ions F⁻¹ added is reduced to 0.125 atomic fractions, the average light and energy of the luminescent brightness on unit cells can be balanced. As indicated in TABLE 2, however, the brightness of the phosphor powder intrinsically exceeds that of the standard phosphor powder. The present inventors emphasize the brightness of the phosphor powder according to the present invention is “intrinsically” enhanced because its luminous efficacy under the radiation excitation of In—Ga—N heterojunction is higher than that of the standard value by 10˜12%; the improvement in luminous efficacy is independent of experimental methods.

This important advantage can be realized in the phosphor powder with cubic garnet structure. The phosphor powder is characterized by the addition of fluorine ions, F⁻¹. The ratio of oxygen ions to fluorine ions in a unit cell is O⁻²:F⁻¹=3:1-50:1 or smaller.

The invention formula according to the present invention does not require a new or supplemental note to eliminate the concept of “coordination polyhedron,” because the cubic unit cell of the compound of the phosphor powder is formed in the coordination polyhedron. The present invention has listed different atoms in the cubic unit cell of the fluorine-oxide garnet phosphor powder: 24 Y atoms of coordination number 8; 16 Al atoms of coordination number 6; and 24 Al atoms of coordination number 4.

The aforementioned description has pointed that the first stoichiometric index “x” changes between x=0.01˜0.3. This indicates that when the concentration of the activator cerium ions is maximum, every unit cell should have 2.5 Ce⁺³ ions. When the concentration of the activator cerium ions is minimum, [Ce⁺³]=0.01, every four unit cells of the new garnet has one activator cerium ion. Obviously, adding fluorine ions into the phosphor powder affects activator cerium ions; moreover, it also affects the radiation of Ce⁺³ ions in special ways: (1) bringing about shortwave shift; (2) destroying the symmetry of the radiation curve and compressing the curve.

These influences are manifested by shifting the shortwave of the spectrum by Δ=17 nm. The shortwave shift of the radiation of Ce⁺³ ions substantially changes the performance the phosphor powder. Polydentate ligands appear in every unit cell of the phosphor powder, i.e. the existence of atoms with two different ratios between O⁻²:F⁻¹=50:1˜3:1. Further, around these two atoms are the main constituents of the phosphor powder: yttrium and aluminum. Also, the maximum of the longwave radiation corresponds to the minimum ratio of O⁻²:F⁻¹.

There is another distinct characteristic of the phosphor powder: the half bandwidth of the spectrum curve can be reduced with the number of radiation quantum, i.e. luminescent brightness, remained unchanged. TABLE 2 indicates that the half bandwidth of the radiation spectrum curve has an intrinsic change, from λ_{0.5}=124 nm to λ_{0.5}=109 nm. Also, this change indicates that the symmetry of the curve is altered; the curve is clearly broadened in the longwave of the spectrum. When the number of radiation quantum remains unchanged and the half bandwidth is reduced, the “degree of concentration” of the spectrum in enhanced, and thus the spectral brightness of the phosphor powder is increased correspondingly; the formula for calculating spectral brightness is L=[L]/Δλ. It is an important parameter for the phosphor powder. By substituting the relative increment of brightness ΔL=112% and the relative decrease of the half bandwidth 66 λ=0.87λₒ, the spectral brightness of the phosphor powder is L=112%/0.87=128.74%. This is the first time that the spectral luminescent brightness can be increased by such a large amount. In previous technical literature and patents, a one third increase from its original brightness value has never been seen.

The aforementioned advantages of the phosphor powder according to the present invention are beyond doubt. In contrast to known phosphor powders, the present phosphor powder can reduce the half bandwidth by reducing the number of fluorine ions (the ratio of oxygen to fluorine is 3:1˜50:1 in a cubic unit cell with a lattice parameter a=119 A).

The aforementioned changes are unusual, but not unique. The experiments conducted by the present inventors indicate that fluorine-oxide phosphor powder can luminesce when excited by LEDs with different maximum spectral wavelength (λ=380˜470 nm). This phenomenon indicates that the excitation spectrum, i.e. the sub-energy band of the radiation spectrum, extends from λ=380 nm to λ=470 nm (an addition of 5 nm can be added if the possible error measurement for LEDs is taken into account.). This kind of change in the excitation spectrum is not seen in traditional YAG:Ce garnet phosphor powder. The wavelength range taken the excitation band (sometimes referred as excitation window) of known standard phosphor powder is λ=445˜470 nm. When the concentration ratio of ligands is O⁻²:F⁻¹=3:1 in the fluorine-oxide phosphor powder, there is a substantial difference between its excitation spectrum and the standard excitation spectrum. The excitation band will be broadened if the concentration ratio of ligands is between 3:1 and 50:1. This is a very important advantage of the fluorine-oxide phosphor powder, characterized in that the excitation spectrum is broad band, λ=380˜470 nm. Moreover, with the changing concentration ratio of ligands O⁻² and F⁻¹) in the fluorine-oxide phosphor powder, the radiation spectrum wavelength of the fluorine-oxide phosphor powder is changed correspondingly in the range of λ=430˜750 nm, and the spectral peak wavelength changes in the range λ=538˜555 nm and the fluctuation of the half bandwidth is λ_{0.5}=124˜109 nm.

Another unique characteristic of the phosphor powder according to the present invention is its lumen equivalence. This parameter is the radiation flux of the phosphor powder under radiation power. There is an additional comment to be added: the maximum lumen equivalence of the narrow band is equal to QL=683 lumen/watt and the suitable peak wavelength is λ=555 nm. It is obvious that the lumen equivalence attains the peak wavelength at λ=555 nm; the shift toward longwave or shortwave will reduce the lumen equivalence, and increasing the shift of the position of the peak wavelength will lead to a greater reduction of lumen equivalence. For this reason, the half bandwidth of the peak wavelength of the phosphor powder according to the present invention is reduced and yet the peak wavelength itself remains unchanged, close to the usual peak wavelength. The following equation can be used to calculate lumen equivalence: QL={λ/λₘₐₓ·683×L/Lₒ}/Δλ, where Δλ=(λ₁−λₒ). λ/λₘₐₓ=0.99 and this index indicates that the peak wavelength is basically the same with the usual peak value. QL=683 lumen/watt. L/Lₒ represents how much the attained brightness exceeds the known brightness. Δλ is the concentration factor of the radiation spectrum of the phosphor powder. According to the patent application, WO 02099902, by A. Srivastava, the half bandwidth of the known garnet phosphor powder, Y₃Al₅O₁₂:Ce, is λ_{0.5}=125 nm and its lumen equivalence is QL=310˜320 lumen/watt. The lumen equivalence of the phosphor powder according to the present invention is QL=1.25×320=400 lumen/watt, which is therefore a very high value. This important advantage of the fluorine-oxide phosphor powder is characterized in that with the ratio of oxygen ions to fluorine ions changing between O⁻²:F⁻¹=3:1˜50:1 in the composition of the phosphor powder, the wavelength of the excitation band changes within the range λ=455˜470 nm and, correspondingly, the lumen equivalence of the radiation spectrum changes between 380˜400 lumen/watt.

The present invention has pointed out that the phosphor powder can luminesce on the yellow-green and yellow sub-energy band of visible light. This is a very important radiation zone because employing paired radiations: blue and yellow, pale blue and orange, blue-green and red, and green and deep red, can produce white radiation according to Newton's Law of Complementary Colors. For the phosphor powder according to the present invention, a complementary color pair emerges from between the blue-violet radiation of semiconductor heterojunction and the yellow-green radiation of phosphor powder. With this advantage, chip producers can broaden the radiation band of semiconductor heterojunction to extend the possible number of chips. This advantage of the fluorine-oxide phosphor powder is characterized in that when the ratio of oxygen ions to fluorine ions changes between 3:1 and 50:1, the spectral peak wavelength changes in the sub-energy band λ=538˜555 nm.

An important and unusual characteristic for the phosphor powder according to the present invention is the total sum of the chromaticity coordinate, Σ(x+y). The total sum of the chromaticity coordinates of a single color in the curves is x+y=1. The chromaticity coordinate listed in TABLE 2 is Σ(x+y)=0.84˜0.92 and the value for a YAG:Ce standard phosphor powder is Σ(x+y)=0.78. This important advantage of the fluorine-oxide phosphor powder is characterized in that with the ratio of oxygen ions to fluorine ions changing between O⁻²:F⁻¹=3:1˜50:1 in the composition of the phosphor powder, the total sum of the chromaticity coordinate changes from Σ=(x+y)0.84 to Σ(x+y)=0.92.

An important radiation performance of the phosphor powder according to the present invention is the color purity of the radiation. Spectroradiometer is employed to validate the value. When the ratio of oxygen ions to fluorine ions changes between O⁻²:F⁻¹=3:1˜50:1 in the crystal of the phosphor powder, the color purity fluctuates in the range α=0.65˜0.75, which is a sufficiently high value.

The significant changes described above concern spectroscopy and colorimetry of the phosphor powder. The present invention has pointed out that, in addition to the changes of chromaticity coordinates and color purity, the color temperature is also changed. The color temperature is a very important parameter for semiconductor lighting; for an ideal black body, color temperature describes the nearness of the total radiation of LEDs and radiation source. Family lighting needs a lower color temperature, T=2700˜3500K, and decoration lights require a higher color temperature, T>4500K. The color temperature of the phosphor powder according to the present invention coincides with the color temperature demanded for the lighting of roads, streets, and buildings at night. The fluctuation range of color temperature of the fluorine oxide is T=4100˜5200K. Also, the value increases with decreasing amount of fluorine ions added into the phosphor powder. High color temperature at night time will increase the radiation contrast of LEDs, thereby providing higher level of lighting comfort.

During the processes of experiments, the present inventors have found another important characteristic of the fluorine oxide; for the excitation light of semiconductor heterojunctions, the phosphor powder particles have a very high absorption capability. If all standard phosphor powders are pale yellow, the reflection coefficient is higher than 80% for the thick layer of phosphor powder particles. On the other hand, the phosphor powder is deep yellow green with a bright color; the reflection coefficient for thick layer of phosphor powder particles is very small, reaching R>26%, which will affect the performance of phosphor powder. During the entire optical process, the phosphor powder will produce reflection (if radiation light reflects toward all directions, it is referred as scattering.), absorption, and luminescence during radiation. For a simplified calculation, all effective quanta will be absorbed and produce luminescence. In such a circumstance, the quantum output of the whole process is taken as 1. Such a condition of the highest possible of quantum output is extremely rare and thus highly unlikely. However, if all light quanta are absorbed and does not luminesce, it is referred as radiationless recombination. Consequently, those producers which cannot produce high quantum-output phosphor powder strive to make the particles phosphor powder with high reflection coefficient. Moreover, the primary blue light quantum from heterojunction reflected many times from the surface of phosphor powder particles are not absorbed yet. Such a refection can reach 5˜8 times and the thickness of the coating of phosphor powder needs to be increased to 200˜280 μm. However, the phosphor powder particles with such a thickness are not suitable for use in LEDs. First, the amount of the transmitted primary blue-light radiation is 20% for the particle layer of phosphor powder; this number is necessary to have a high quality white light. Second, a thick particle layer of phosphor powder has low heat conductivity and heterojunction is likely to burn out during working.

In practical, thin particle layer of phosphor powder is more favorable. Other conditions have to be met as follows: (1) phosphor powder particles should have a very high light transparency; (2) phosphor powder particles should have a high absorption capability to absorb the excitation light of heterojunction; (3) phosphor powder particles should have a very high luminescence quantum output. It has to point that the present inventors have achieved all three conditions during experiments.

During the experiments, the inventors find that modulating the addition of fluorine ions can control the reflection coefficient of the particles layer of the phosphor powder, in which the ratio of oxygen ions to fluorine ions is O⁻²:F⁻¹=3:1˜50:1. After the absorption of phosphor powder being enhanced, it is possible to create LEDs with spectral-transformation thin layer of phosphor powder. The advantage of the fluorine-oxide phosphor powder according to the present invention is characterized in that its composition is added with phosphor powder containing fluorine ions, F⁻¹, as ligands, and the reflection coefficient of the particles is R≦26% on the shortwave sub-energy band of wavelength λ=400˜500 nm, and R=32-38% on the yellow region of the spectrum.

The enhanced capability of effective absorption for phosphor powder particles is closely related to the high quantum output of radiation. According to related literature, the YAG:Ce phosphor powder has a quantum output of about 80˜90%. Other garnet phosphor powder such as Gd—Y has a lower quantum output; the Gd—Y garnet phosphor powder synthesized at 1520˜1560° C. has a somewhat higher quantum output. For the phosphor powder according to the present invention, the sample obtained during experiments shows a very high quantum output. Organic substance-phosphor powder is employed as a standard for the measurement of quantum output. Within the excitation wavelength λ=400˜500 nm, the quantum output of the substance remains constant, η=0.97. Using this substance as a standard, the present inventors find that the quantum output of the phosphor powder according to the present invention is not constant; the quantum output of the phosphor powder is dependent on the amplitude of the emitted light. Namely, the quantum output changes with the longwave of the spectrum curve obtained from spectroradiometer. The quantum output obtained in the present invention has a minimum value of η=0.96. If the complexity of the measurement method and other reasons are taken into account, the measurement value is likely to have some error. For example, the reflection of the phosphor substance as standard sample is a completely different spectrum. The present inventors consider that with different addition of fluorine ions into the phosphor powder, the quantum output of the phosphor powder according to present invention is larger than or equal to 0.96 (η≧0.96). This advantage of the phosphor powder is characterized in that when the photo-excitation band is λ=455±15 nm, the output quantum of the phosphor powder radiation increases with decreasing addition of fluorine ions, η≧0.96.

Another desirable characteristic of the phosphor powder is its high thermal stability. The parameter of thermal stability can be used to estimate the temperature sensitivity range of the phosphor powder. When the known YAG:Ce phosphor powder is heated to T=100° C., its luminous intensity is reduced by 25%; if it is heated to T=130˜135° C., its luminous intensity will be reduced by half, to 50% of the original value.

In the experiments, the present inventors find that the addition of fluorine ions, F⁻¹, into the crystal of the phosphor powder mainly containing Y⁺³ and/or Ce⁺³, will substantively enhance the thermal stability of the phosphor powder. When the phosphor powder according to the present invention is heated to T=150˜165° C., the luminous intensity is only reduced by 25%. If the phosphor powder is used in watt-scale LEDs, simple radiators such as metal pads or gold-plated washer can be used. This advantage of the phosphor powder according to the present invention also includes that it can enhance the excitation power of heterojunction without lowering the luminous intensity.

The thermal stability of the fluorine-oxide is characterized in that when it is heated to T=100˜165° C., the luminous intensity is only reduced by 15˜25%.

During the entire experimental process, the color, color temperature, thermal stability, excitation light absorption, and quantum output of the phosphor powder are examined. Moreover, the shape of radiation curve and the asymmetry of the curve of the phosphor powder are also studied. As described earlier, the radiation curve of the phosphor powder can be represented by Gauss function. Furthermore, the spectral asymmetry is characterized by its shifting toward the long wavelength region and this shift also points out that the peak wavelength does not coincide with the dominant wavelength.

Apart from the inconsistency between the peak wavelength λₘₐₓ and dominant wavelength λ, these two values are determined by the addition of fluorine ions into the phosphor powder. With increasing concentration of fluorine ions in the phosphor powder, the dominant wavelength decreases, leading to the increase of the radiation fraction of the major spectrum, i.e. enhancing the radiation performance of the phosphor powder.

The present invention has found a specialized process for producing the phosphor powder. The garnet phosphor powder is usually produced by heat treating oxides raw materials. For the chemical reaction to produce yttrium aluminate (YAlO₃), Y₂O₃+Al₂O₃→2YAlO₃ (stoichiometry equation 1), BaF₂ is used as an catalyst. BaF₂ does not dissolve during the reaction, and it can be washed away with acid. The catalytic function of BaF₂ is to accelerate the aforementioned reaction. During the process of high-speed synthesis of garnet, BaF₂ does not have enough time to decompose and thus accumulate in the ingredients. However, it has to point out again that the only oxides used as ingredients are Y₂O₃ and Al₂O₃.

The foundation for the process according to the present invention is that at least one of the fluorides YF₃ and YOF are used as the ingredient; the ingredient can strongly catalyze the formation of the garnet with two ligands, Y₃₋ₓCeₓAl₂(AlO_{4-γ}F_{O)γ}F_{i)γ})₃, and the fluoride is able to remain in the final product to change the structure of the phosphor powder.

Consistent with the heat treatment process proposed earlier, the processing temperature for the phosphor powder is lower than that for ordinary YAG:Ce phosphor powder by about 100° C. This is beneficial to the operation of high-temperature equipments and to the consumption of crucibles.

The furnace used for synthesizing the fluorine-oxide phosphor powder has eight different temperature zones, between which is the temperature difference of +300 and +400° C. The entry of the furnace is kept at +100° C. To obtain high quality phosphor powder, the furnace has to be filled with fluorine-containing reducing atmosphere, whose volume constitution is H₂:N₂:HF=5:94.99:0.01. The crucible is then removed from the furnace and cooled; the phosphor powder is ground in a mortar. Then, the ground particles are undergone final treatment. The phosphor powder is treated one hour in a hot nitric acid solution (1:1). After being washed with acid, it is put into a ZnSO₄(10 g/L) and Na₂SiO₃(10 g/L) solution and treated with an ultra-sonic wave (with a power of 100 watt) to form an inorganic oxide (ZnOₙSiO₂) film of 100 nm on the particles surface of the phosphor powder. The chemical compositions of the phosphor powder made from this process are shown in TABLE 2. The phosphor powder of this composition has very high lighting parameters. Consequently, the LEDs using the phosphor powder will also show very high lighting parameters.

This important advantage of the fluorine-oxide phosphor powder is characterized in that the phosphor powder is synthesized by heat treatment process. The specific steps for the process are as follows: Yttrium and/or cerium fluoride and/or fluorine oxide are used as ingredients, which are combined with aluminum oxide and cerium oxide according to chemical stoichiometry. The weighed ingredients are put into a furnace for heat treatment process. The furnace is filled with fluorine-containing reducing atmosphere, containing H₂:N₂:HF=5:94.99:0.01. The phosphor powder is heat treated at the temperature 900˜1520° C. for 12 hours. The final product is washed with acid in a hot nitric solution (1:1) for an hour to form a ZnOₙSiO₂ thin film on the particles surface of the phosphor powder. The final phosphor powder is yellow particles, which are then measured for lighting parameters.

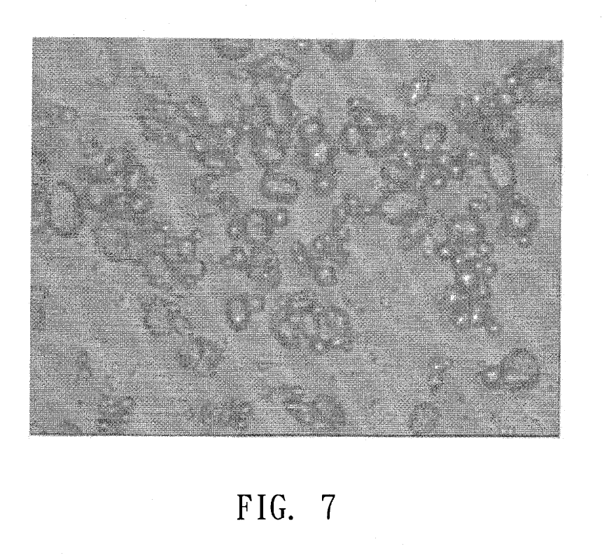

In addition to the measurement of lighting parameters, the particles size of the phosphor powder is also measured. The morphology and light transparency of the phosphor powder particles are also examined by microscopy. FIG. 7 shows the morphology of the phosphor powder particles with the ratio of oxygen ions to fluorine ions as O⁻²:F⁻¹=15:1. The particles in FIG. 7 are round with multiple facets.

The mean diameter of the phosphor powder particles is d_{cp}=2.2˜4.0 μm, the median diameter is d₅₀=1.60˜2.50 μm, and the specific area is S=28˜42×10³ cm²/cm³.

This important advantage of the phosphor powder according to present invention is characterized in that the particles are round, the mean diameter is d_{cp}=2.2˜4.0 μm, the median diameter is d₅₀=1.60˜2.50 μm, and the specific area is S=42×10³ cm²/cm³.

It has to point out that there are 50% of the particles larger than the median diameter and 50% of them are smaller and all the particles have a basically same mean diameter. This result indicates that the particles size of the phosphor powder is very small and there is no sintered blocks. Also, the particles of the phosphor powder have regular planes and facets; this kind of particles morphology can be compressed together. The particles have a very high specific area, reaching 42×10³ cm²/cm³.

The following description is related to the semiconductor LEDs based on In—Ga—N heterojunctions, and the structure of LEDs will not be explained in details. Two power terminals are near the luminescent heterojunction (PN junction). The thickness of the heterojunction thin plate is usually 250˜300 μm with a surface area reaching 1 mm² or 1.5 mm². The luminescent surface of the heterojunction has a light conversion layer, which is used to convert part of the shortwave form of the heterojunction into yellow fluorescent radiation. It has to stress one point in particular here that, apart from its surface, the light conversion layer can also concentrate all the radiant light of the semiconductor heterojunction from its radiant facets. Consequently, the light conversion layer is necessary to be filled with viscous liquid polymer, for example, silicone with a molecular mass of 12˜16×10³ carbon unit or epoxy resin with a molecular mass of 20˜22×10³ carbon unit. The molecular ratio of the phosphor powder particles in the polymer adhesive is 5˜45%. The most appropriate mass concentration of the phosphor powder is 18˜22%. To prepare the adhesive for the phosphor powder conversion layer, specific amounts of phosphor powder and polymer adhesive are first weighed and curing agent is then added. The mixture is then thoroughly stirred in an ultrasonic apparatus to prevent excessive gas holes from forming.

The phosphor powder mixture is then polymerized at T=85˜120° C. to become flat yellow thin film, which covers all the surfaces of the heterojunction. If the polymer layer of high viscosity has a uniform thickness, the emitted light toward all sides from the heterojunction covered with light conversion layer will also be uniform.

The light conversion layer is characterized in that the light conversion layer is formed as a geometrical shape with a uniform thickness and is optically contacted with the luminescent surfaces and facets of heterojunction to form a lighting source. The resulted radiation spectrum comprises the primary shortwave radiation of the heterojunction of wavelength λ=450˜470 nm and the secondary phosphor radiation of the fluorine-oxide phosphor powder.

The heterojunction filled with the phosphor-powder conversion layer is usually located at the cone-shape concentrator, which guides the collected light into the lens cover of LEDs. The lens can be in a variety of shapes: cylindrical, spherical, or conical.

When voltage is applied to the power terminals of LEDs, a large amount of current (20˜500 mA) flows through the semiconductor heterojunction to induce electroluminescence. The final white light obtained from LEDs comprises two lights, i.e. blue light and yellow-green light. White light has its own radiation spectrum curve and, as described earlier, comprises two radiation spectrums.

The LEDs filled with phosphor-powder conversion layer containing phosphor powder is based on semiconductor In—Ga—N heterojunction and is characterized in that the semiconductor light source produces an overall radiation, which comprises two spectrum curves. The peak wavelength of one of the spectrum curves is λ_{|}=460±15 nm and the other is λ_{∥}=547±8 nm. The chromaticity coordinate of the radiation spectrum is x=0.32±0.04 and y=0.32±0.02, similar to the standard C type light source.

The present invention also presents other lighting parameters of the semiconductor light source. These parameters are very high. For example, the central luminous intensity at 2θ=30° is I>100 candela. The LEDs with a power of W=1 watt have a luminous flux of 85˜105 lumens and thus its luminescent efficiency is η≧85 lumen/watt. Undoubtedly, this is a very favorable parameter for current semiconductor light source because so far the luminescent efficiency generally does not exceed 60˜70 lumen/watt. Certainly, this important advantage of the LEDs is closely related to the high-performance parameters of the fluorine-oxide phosphor powder used here.

The fluorine-oxide phosphor powder not only can be used in semiconductor heterojunction, but also can be used for nuclear radiation detectors, specialized tritium light sources, or even liquid crystal display.

Chemical elements have stability; i.e. un-decayed isotopes are unstable, or referred as radioactive. There are a series of this kind of radioactive elements in natural world, for example, K⁴⁰ or C¹⁴. These isotopes will emit different substances such as electrons, β-particles, α-particles, or He⁴ during decay.

These isotopes are artificial substances and usually emit γ rays in addition to α- and β-particles during decay. These substances are monitored with radiation dose meter and radiation detector; the underlying working principle of the detector is fluorescent effect because many phosphor powder will flash when applied with α and β particles as well γ quanta. To monitor radioactive substance, light sensor containing phosphor powder is employed to record the luminous intensity under the action of different radioactive substances. According to the detected luminous intensity, the radioactivity of artificial and natural substances or isotopes can be determined. One point worth mentioning is that the phosphor powder in the light sensors should be able to discern the interaction between α and β particles as well γ quanta. The fluorine-oxide phosphor powder according to the present invention emits strong yellow-green light under the action of α particles (for example, isotope Pₒ²¹⁰) and β particles (for example, isotope ₆C¹⁴) as well as γ rays (for example, the radiation source Cₒ⁶⁰ with energy of E=1.17 MeV).

These scintillation sensors according to the present invention are based on fluorine-oxide phosphor powder. The light transparent polymer of the sensor is filled with the phosphor powder to form very condensed composite of polymer and phosphor powder.

The scintillation sensor according to the present invention has another important property: the scintillation flash it emitted has a very short decay time, less than 100 nanoseconds. The phosphor powder suitable for scintillation sensors has a mean diameter of d≧10 μm, a median diameter of d₅₀=5±0.5 μm, and a specific area of S≦18×10³ cm²/cm³. The phosphor powder particles in the light transparent polymer can detect α and β particles of energy 10˜12 MeV and γ quanta of energy 1.6 MeV.

Special polymers, polycarbonate for example, can be combined with the phosphor powder to make scintillation sensors, in which the mass concentration of the phosphor powder in polycarbonate is 5˜40%. A thin film (a thickness of 150˜300 μm) is formed from the suspensoid of phosphor powder and polycarbonate in a special pouring apparatus. Then the phosphor powder condenses to form a cylindrical shape, inside which a high-speed photo-electronic detector is inserted. According to the present experimental data, the scintillation sensors can flash in a rate of 38˜52×10³ times/sec when the energy of the excited quantum of γ rays is 1 MeV. This scintillation sensor has a very high sensitivity and is characterized in that the sensor is based on the fluorine-oxide phosphor powder according to the present invention.

There is another implicit application for the fluorine-oxide phosphor powder according to the present invention concerning its high sensitivity for the β rays of the isotope T³. This artificial isotope is characterized in that the electron energy emitted by β rays is E=12˜18 MeV. A small glass tube is applied with the fluorine-oxide phosphor powder on its inner surface and is then filled with tritium. The glass tube will emit uniform light for years (the half life of the isotope T³ is nine years.) and goes off eventually. The glass tube needs to be plugged to prevent the radioactive tritium gas from dissipating and can be used in many fields; for example, it can be used as the light source of aiming lights in many firing weapons.

Applying the fluorine-oxide phosphor powder as a fluorescent layer is characterized in that the fluorescent layer can be excited by the β rays of energy E=17.9 MeV emitted by the radioactive isotope T³. The brightness of the excited light is L=2˜4 candela/m², and it decays only 25% in 3.5˜4 years.

The fluorine-oxide phosphor powder can be excited to produce light under low-voltage current. Therefore, the phosphor powder can be applied as dense cathode fluorescent layer in FED (Field Emission Display) monitor. The main requirements of FED monitors are that the fluorescent layer can emit light under the electron beams with relatively low energy (E=500˜2000 eV), and the phosphor powder has to have a small particles size and high brightness. The fluorine-oxide phosphor powder according to the present invention has met both requirements: it can be excited to emit light under very low energy and has a very small particle size. The fluorescent layer can emit yellow-green light under the electron beams with energy of E=200˜1000 eV.

Consequently, the fluorine-oxide phosphor powder has a series of distinct properties and can emit light under the excitation of shortwave and low-voltage electron beams: β ray and γ quantum.

In summary, the fluorine-oxide phosphor powder according to the present invention can be used as a light conversion layer of cold white LEDs based on In—Ga nitride semiconductor heterojunction, and can render one-watt LEDs to achieve a luminescent efficiency of η=85-105 lumen/watt; the fluorine-oxide phosphor powder can be applied in nuclear-radiation scintillation sensors, in which the energy of the excited particles is 1 MeV and the light emitted reaches 38˜52×10³ time/second; the fluorine-oxide phosphor powder can be applied in FED monitors to produce clear images; and the fluorine-oxide phosphor powder can be applied as a spectrum converter of solar cells based on single crystal silicon and can increase the efficiency of solar cells by 18-22%. Consequently, the fluorine-oxide phosphor powder according to the present invention can indeed overcome the prior drawbacks.

It is appreciated that although the directional practice device of the present invention is used in a very limited space instead of practicing at the real playing field, effective and steady practice can be obtained as well. Further, it is very easy to set up and to operate the directional practice device of the present invention. These advantages are not possible to achieve with the prior art.

While the invention has been described with reference to the a preferred embodiment thereof, it is to be understood that modifications or variations may be easily made without departing from the spirit of this invention, which is defined by the appended claims.

What is claimed is:

1. A fluorine-oxide phosphor powder, based on the cubic-garnet fluorine oxide and yttrium aluminum oxide, using cerium as activator, and characterized in that the luminescent material is added with fluorine with a chemical equivalence formula as Y₃₋ₓCeₓAl₂(AlO_{4-γ}F_{O)γ}F_{i)γ})₃, wherein F_{O} is fluorine ion in the lattice point of oxygen crystal and Fᵢ is fluorine ion between lattice points.

2. The fluorine-oxide phosphor powder as defined in claim 1, wherein the stoichiometric indexes of the chemical equivalence formula are 0.0011≦γ≦1.5 and 0.001≦x≦0.3, and the lattice parameter of the luminescent material is a≦1.2 nm.

3. The fluorine-oxide phosphor powder as defined in claim 1, wherein the fluorine-oxide phosphor powder has a broad-band excitation spectrum of wavelength λₑₓₜ=380˜470 nm, the radiation wavelength of λ=420˜750 nm, the peak wavelength of λₘₐₓ=538˜555 nm, and the maximum half bandwidth of λ_{0.5}=109˜114 nm.

4. The fluorine-oxide phosphor powder as defined in claim 1, wherein when the excitation wavelength of the phosphor powder is λ=458 nm, the lumen equivalence of the radiation spectrum fluctuates in the range of QL=360˜460 lumen/watt.

5. The fluorine-oxide phosphor powder as defined in claim 1, wherein the phosphor powder excited by the near violet-visible light emits yellow-green light with the peak wavelength of λ=538˜555 nm.

6. The fluorine-oxide phosphor powder as defined in claim 1, wherein the afterglow period of the phosphor powder is τₑ=60-88 nanoseconds when excited by the light of λ=450˜470 nm.

7. The fluorine-oxide phosphor powder as defined in claim 1, wherein the reflection index R of the phosphor powder is less than 20%, R≦20%, in the short-wavelength sub-energy band of λ=400˜500, and the reflection index in the yellow-green zone of the spectrum is R=30-35%.

8. The fluorine-oxide phosphor powder as defined in claim 1, wherein the luminous intensity of the phosphor powder decreases by 12˜25% when T=100˜175° C.

9. The fluorine-oxide phosphor powder as defined in claim 1, wherein under the excitation band of λ=460±10 nm, the radiation quantum output of the phosphor powder is η≧0.96 and the quantum output increases with increasing concentration of fluorine ions from [F]=0.01 to [F]=0.25.

10. The fluorine-oxide phosphor powder as defined in claim 1, wherein the radiation spectrum of the phosphor powder can be represented by Gaussian curve and the dominant wavelength increases from λ=564 nm to λ=568 nm.

11. The fluorine-oxide phosphor powder as defined in claim 1, wherein the particles of the phosphor powder are roughly spherical with 12 and/or 20 facets, mean diameter is d_{cp}=2.2˜4.0 μm, median diameter is d₅₀=1.60˜2.50 μm, and also the specific area reaches 42×10³ cm²/cm³.

12. A spectrum converter used in In—Ga—N heterojunction, based on the phosphor powder as defined in claim 11, which is filled with the phosphor powder in its transparent polymer layer and is characterized in that the spectrum converter is formed as a geometrical shape with a uniform thickness and becomes a light source by optically contacting with the planes and side planes of the heterojunction, its radiation spectrum consists of the primary radiation of λ=450˜470 nm short-wavelength heterojunction and the regenerated radiation of the aforementioned phosphor powder, and the filled phosphor powder has an appropriate concentration to produce white light with a color temperature of T=4100˜6500K.

13. A semiconductor light source, based on spectrum converters and the planes and facets of the In—Ga—N heterojunction is distributed with the phosphor powder as defined in claim 11, which is characterized in that the overall radiation comprises two spectrum curves, of which the first spectrum curve has the peak wavelength at λₘₐₓ=460±10 nm and the second spectrum curve has the peak wavelength at λₘₐₓ=546±8 nm, with the chromaticity coordinate being x=0.30˜0.36 and y=0.31˜0.34.

14. The semiconductor light source as defined in claim 13, wherein under the luminous flux of the unit heterojunction, the luminous intensity is I>100 candela, 2θ=30°, and the luminescent efficiency is η>85 lumen/watt.

15. A scintillating phosphor powder, having the chemical composition of the phosphor powder as defined in claim 1 and characterized in that the particles of the scintillating phosphor powder have a mean diameter d≧10 μm, a median diameter d₅₀=5±0.5 μm, and a specific area S≦18×10³ cm²/cm³, and can scintillate when excited by γ ray of energy 1.6 MeV or high-energy particles.

16. The scintillating phosphor powder as defined in claim 15, wherein the high-energy particle may be β-electron and the scintillation light of the scintillating phosphor powder is the yellow-green light region of the visible light, with a decay time less than 100 nanoseconds,

17. A scintillation sensor, based on the phosphor powder as defined in claim 15, which is distributed in light transparent polycarbonate with an average molecular weight M=18˜20×10³ carbon unit and accounts for 40% of mass of the scintillation sensor, is characterized in that the scintillation sensor scintillates 38˜52×10³ time/second under the excitation of 1 MeV particles or γ radiation quanta.

18. A glass tube on its inner surface having a light radiation layer, having the fluorine-oxide phosphor powder as defined in claim 1, and characterized in that the air of the light radiation layer contains the tritium isotope, ₁T³, emitting β-ray with energy E=17.9 keV, which excites the phosphor powder particles to luminesce with an initial luminescent brightness L=2˜4 candela/m² and decay 25% of the luminescent brightness in 3.5˜4 years.

19. A FED (Field Emission Display) monitor, in which the radiation emitted from its anodic phosphor powder layer is related to the impingement of electron beams, characterized in that the phosphor powder particles of the phosphor powder layer as defined in claim 1 emits yellow-green light under the excitation of electron with energy E=250˜1000 eV.

20. A display containing phosphor powder particles layer, characterized in that the mean diameter of the particles of the phosphor powder layer is d_{cp}≦1 μm and the median diameter is d₅₀≦0.6 μm.
